(19) United States
(12) Patent Application Publication
(10) Pub. No.: US 2025/0266830 A1
(43) Pub. Date: Aug. 21, 2025

(54) SEMICONDUCTOR SYSTEM FOR DETECTING PROCESS VARIATION

(71) Applicant: SK hynix Inc., Icheon-si Gyeonggi-do (KR)

(72) Inventor: Dae Joon KIM, Icheon-si Gyeonggi-do (KR)

(73) Assignee: SK hynix Inc., Icheon-si Gyeonggi-do (KR)

(21) Appl. No.: 18/740,942

(22) Filed: Jun. 12, 2024

(30) Foreign Application Priority Data
Feb. 19, 2024 (KR) 10-2024-0023845

(51) Int. Cl. H03K 17/687; G11C 8/18; H03K 21/08

(52) U.S. Cl. CPC H03K 17/6872; H03K 21/08; G11C 8/18

(57) ABSTRACT

A semiconductor device includes a comparison circuit configured to generate a flag signal by comparing a voltage level of a reference voltage with a voltage level of a process voltage after the start of a process variation detection operation and a process information generation circuit configured to generate a process detection signal that indicates process variation based on a counting detection signal that is generated based on the flag signal and based on timing of pulses included in a cycle signal.

### CROSS-REFERENCE TO RELATED APPLICATION

The present application claims priority under 35 U.S.C. § 119(a) to Korean Patent Application No. 10-2024-0023845, filed in the Korean Intellectual Property Office on Feb. 19, 2024, the entire disclosure of which application is incorporated herein by reference.

### BACKGROUND

The present disclosure relates to a semiconductor system for detecting process variation.

An operating speed of a semiconductor system has been continuously improved along with an increase in the degree of integration of semiconductor systems. As the degree of integration and speed of semiconductor systems increases, operating error of semiconductor systems results when an internal process variation occurs.

### SUMMARY

In an embodiment, a semiconductor device may include a comparison circuit configured to generate a flag signal by comparing a voltage level of a reference voltage with a voltage level of a process voltage after the start of a process variation detection operation and a process information generation circuit configured to generate a process detection signal that indicates process variation based on a counting detection signal that is generated based on the flag signal and based on timing at of pulses included in a cycle signal.

In an embodiment, a semiconductor device may include a cycle signal generation circuit configured to generate a cycle signal having pulses generated at timing that varies depending on process variation, a counting detection signal generation circuit configured to generate a counting detection signal by comparing a target counting signal with a counting signal that counts pulses of the cycle signal, and a process information generation circuit configured to generate a process detection signal that indicates process variation based on the counting detection signal and a flag signal.

In an embodiment, a semiconductor device may include a comparison circuit configured to generate a plurality of flag signals in response to detecting a voltage level of a process voltage having a voltage level that varies depending on process variation, a counting detection signal generation circuit configured to generate a plurality of counting detection signals by comparing a counting signal with a first target counting signal, a second target counting signal, a third target counting signal, and a fourth target counting signal, wherein the counting signal counts pulses of a cycle signal having pulse timing that varies depending on the process variation, and a process information generation circuit configured to generate a plurality of process detection signals that indicate the process variation based on the plurality of counting detection signals and the plurality of flag signals.

In an embodiment, a method may include generating a plurality of flag signals in response to detecting a process voltage that varies depending on process variation of a semiconductor device; generating a counting signal that counts pulses of a cycle signal having pulse timing that varies depending on the process variation; generating a plurality of counting detection signals by comparing the counting signal with each of a plurality of target counting signals; and generating a process information signal that indicates the process variation based on the plurality of counting detection signals and the plurality of flag signals.

### BRIEF DESCRIPTION OF THE DRAWINGS

FIG. 1 is a block diagram illustrating a semiconductor system according to an embodiment of the present disclosure.

FIG. 2 is a block diagram illustrating a semiconductor device that is included in a semiconductor system according to an embodiment of the present disclosure.

FIG. 3 is a diagram illustrating a cycle signal generation circuit of a semiconductor device according to an embodiment of the present disclosure.

FIG. 4 is a diagram illustrating a comparison circuit of a semiconductor device according to an embodiment of the present disclosure.

FIG. 5 is a block diagram illustrating a flag signal generation circuit according to an embodiment of the present disclosure.

FIG. 6 is a diagram illustrating a comparison voltage signal generation circuit according to an embodiment of the present disclosure.

FIG. 7 is a voltage diagram illustrating process voltages that are generated depending on process variation and reference voltage according to an embodiment of the present disclosure.

FIG. 8 is a circuit diagram illustrating a flag signal decoding circuit according to an embodiment of the present disclosure.

FIG. 9 is a table including data output during operation of a flag signal decoding circuit according to an embodiment of the present disclosure.

FIG. 10 is a block diagram illustrating a counting detection signal generation circuit according to an embodiment of the present disclosure.

FIG. 11 is a diagram illustrating a counting comparison circuit for a counting detection signal generation circuit according to an embodiment of the present disclosure.

FIG. 12 is a table including data output during operation of counting comparators according to an embodiment of the present disclosure.

FIG. 13 is a table including data output during operation of logic circuits of a counting comparison circuit according to an embodiment of the present disclosure.

FIG. 14 is a circuit diagram illustrating a process information generation circuit according to an embodiment of the present disclosure.

FIG. 15 is a table including data output during an operation of a process information generation circuit according to an embodiment of the present disclosure.

FIG. 16 is a diagram illustrating an embodiment of an electronic system including a semiconductor system according to an embodiment of the present disclosure.

### DETAILED DESCRIPTION

Methods of detecting internal process variation, such as process variation during semiconductor fabrication or process variation due to performance degradation or variation as a semiconductor ages, for example, resulting from circuit mismatch, and methods of modifying the process variation for semiconductor systems are desirable. In general, process variation may be detected by comparing a voltage that varies depending on process variation with reference voltages levels that are constant despite process variation. Methods of accurately detecting process variation are desirable.

Terms such as “first” and “second,” which are used to distinguish among various components, the components are not limited by these terms. For example, a first component may be referred to as a second component and vice versa.

When one component is referred to as “connected” to another component, the components may be directly connected to each other or connected to each other through another component interposed therebetween. When one component is referred to as “directly connected” to another component, the components are directly connected to each other without another component interposed therebetween.

A “logic high level” and a “logic low level” are used to describe the logic levels of signals. A signal at a “logic high level” is distinguished from a signal at a “logic low level.” For example, when a signal at a first voltage corresponds to a signal at a “logic high level,” a signal at a second voltage may correspond to a signal at a “logic low level.” According to an embodiment, a “logic high level” is a voltage higher than a “logic low level.” According to an embodiment, the logic levels of signals may be different logic levels or opposite logic levels. For example, a signal at a logic high level may be at a logic low level in some embodiments, and a signal at a logic low level may be at a logic high level in some embodiments.

The present disclosure is described in more detail through embodiments. The embodiments are only used to illustrate the present disclosure, and the scope of the present disclosure is not limited by the embodiments.

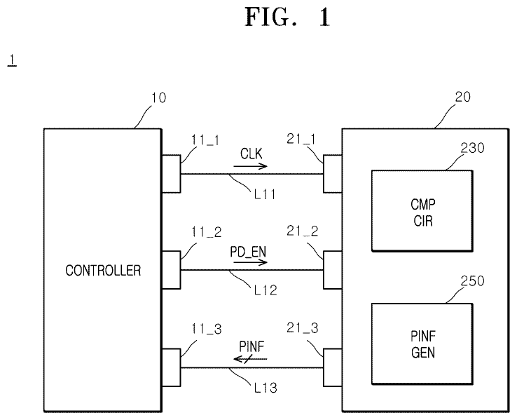

As illustrated in FIG. 1, a semiconductor system 1 according to an embodiment of the present disclosure includes a controller 10 and a semiconductor device 20.

The controller 10 includes a first control pin 11_1, a second control pin 11_2, and a third control pin 11_3. The semiconductor device 20 includes a first device pin 21_1, a second device pin 21_2, and a third device pin 21_3. A first transmission line L11 is connected between the first control pin 11_1 and the first device pin 21_1. A second transmission line L12 is connected between the second control pin 11_2 and the second device pin 21_2. A third transmission line L13 is connected between the third control pin 11_3 and the third device pin 21_3. The controller 10 transmits a clock signal CLK to the semiconductor device 20 through the first transmission line L11. The controller 10 transmits a process detection enable signal PD_EN to the semiconductor device 20 through the second transmission line L12. The controller 10 receives a process information signal PINF from the semiconductor device 20 through the third transmission line L13. The clock signal CLK is a signal that is periodically toggled in order to synchronize operations of the controller 10 and the semiconductor device 20. The process detection enable signal PD_EN is a signal that is enabled to initiate performing a process operation. The process information signal PINF, used to indicate the process variation including variance of the process variation, is a signal that includes a plurality of bits generated based on a cycle signal having pulse generation timing that varies depending on process variation. The process information signal PINF is generated after the start of a process detection operation and is based on the voltage level of a process voltage that has a voltage level that varies depending on process variation.

The semiconductor device 20 includes a comparison circuit CMP CIR 230 and a process information signal generation circuit PINF GEN 250.

The comparison circuit 230 generates a flag signal based on the voltage levels of a reference voltage and the process voltage after the start of a process variation detection operation while the process detection enable signal PD_EN is enabled. The comparison circuit 230 generates the flag signal by comparing the voltage levels of a reference voltage and the process voltage PV after the start of a process variation detection operation.

The process information signal generation circuit 250 generates the process information signal PINF based on the cycle signal and the flag signal after the start of a process variation detection operation. The process information signal generation circuit 250 generates, after the start of a process variation detection operation, the process information signal PINF based on the flag signal that is generated based on the cycle signal having pulse generation timing that varies depending on process variation and the voltage level of the process voltage. After the start of a process variation detection operation, the process information signal generation circuit 250 generates the process information signal PINF based on a counting detection signal that is generated based on the flag signal and pulse timing within the cycle signal.

After the start of a process variation detection operation while the process detection enable signal PD_EN is enabled, the semiconductor device 20 generates the flag signal by comparing the voltage levels of a reference voltage and a process voltage having a voltage level that varies depending on process variation. After the start of a process variation detection operation, the semiconductor device 20 generates the process information signal PINF that indicates process variation and is based on the flag signal and the counting detection signal that is generated based on timing of pulses of the cycle signal.

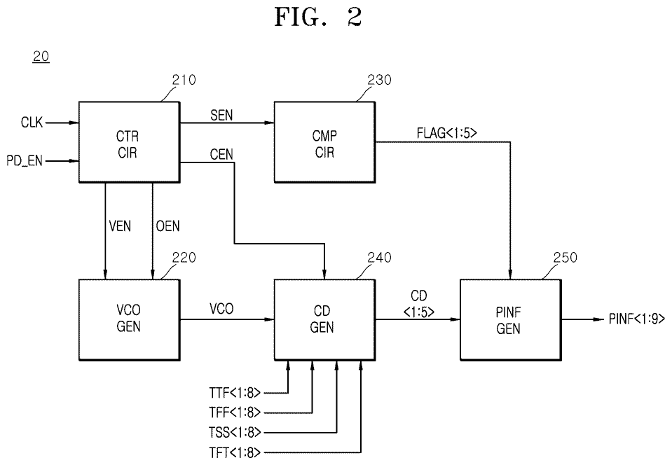

FIG. 2 is a block diagram illustrating an embodiment of the semiconductor device 20. As illustrated in FIG. 2, the semiconductor device 20 includes a control circuit CTR CIR 210, a cycle signal generation circuit VCO GEN 220, the comparison circuit CMP CIR 230, a counting detection signal generation circuit CD GEN 240, and the process information signal generation circuit PINF GEN 250.

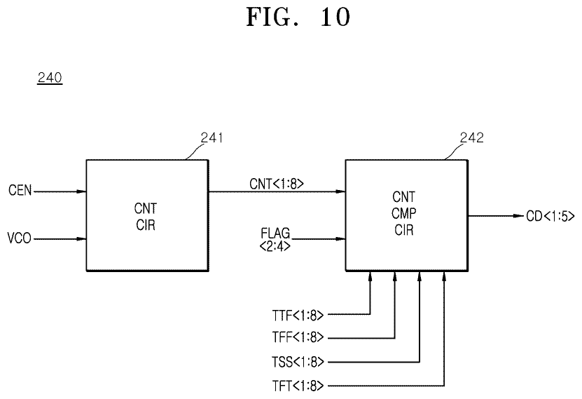

The control circuit 210 generates, based on the process detection enable signal PD_EN in synchronization with the clock signal CLK, a voltage enable signal VEN, a cycle enable signal OEN, a comparison enable signal SEN, and a counting enable signal CEN. The control circuit 210 generates the voltage enable signal VEN that is enabled at a logic high level at the time when the process detection enable signal PD_EN is enabled in synchronization with the clock signal CLK, for example, the rising edge of the voltage enable signal VEN occurs in synchronization with the clock signal CLK at a time when the process detection enable signal PD_EN is enabled at a logic high level. The control circuit 210 generates the cycle enable signal OEN that is enabled at a logic high level at the time when the process detection enable signal PD_EN is enabled in synchronization with the clock signal CLK, for example, the rising edge of the cycle enable signal OEN occurs in synchronization with the clock signal CLK at a time when the process detection enable signal PD_EN is enabled at a logic high level. The control circuit 210 generates the comparison enable signal SEN that is enabled at a logic high level at the time when the process detection enable signal PD_EN is enabled in synchronization with the clock signal CLK, for example, the rising edge of the comparison enable signal SEN occurs in synchronization with the clock signal CLK at a time when the process detection enable signal PD_EN is enabled at a logic high level. The control circuit 210 generates the counting enable signal CEN that is enabled at a logic high level during an interval starting at the time when the process detection enable signal PD_EN is enabled in synchronization with the clock signal CLK, for example, the rising edge of the counting enable signal CEN occurs in synchronization with the clock signal CLK at a time when the process detection enable signal PD_EN is enabled at a logic high level, and the counting enable signal CEN remains at a logic high level for the duration of the interval. The interval is a time period during which a counting signal (CNT<1:8> in FIG. 10) is output as a count of pulses of a cycle signal VCO generated during the interval.

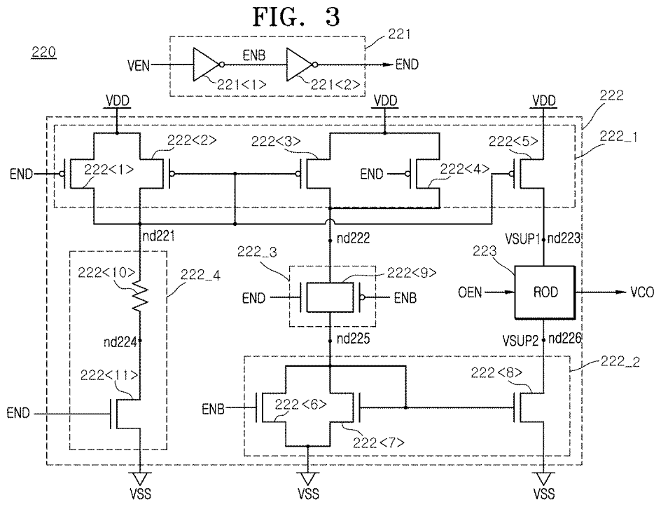

While the voltage enable signal VEN is enabled, the cycle signal generation circuit 220 supplies an oscillator ROD (223 in FIG. 3) with a first supply voltage (VSUP1 in FIG. 3) and a second supply voltage (VSUP2 in FIG. 3). While the cycle enable signal OEN is enabled, the cycle signal generation circuit 220 generates the cycle signal VCO in the form of pulses that are periodically generated from the first supply voltage (VSUP1 in FIG. 3) and the second supply voltage (VSUP2 in FIG. 3). The cycle signal VCO is a signal comprising pulses generated at timing that varies depending on process variation.

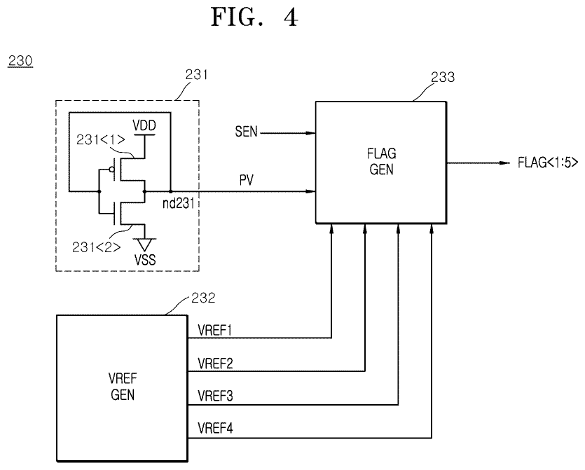

The comparison circuit 230 generates a flag signal FLAG<1:5> based on the voltage levels of a reference voltage (VREF1, VREF2, VREF3, and VREF4 in FIG. 4) and a process voltage (PV in FIG. 4) at a voltage level that varies depending on process variation. The comparison circuit 230 generates the flag signal FLAG<1:5> by comparing the voltage levels of the reference voltage (VREF1, VREF2, VREF3, and VREF4 in FIG. 4) with the process voltage (PV in FIG. 4) that has a voltage level that varies depending on process variation while the comparison enable signal SEN is enabled. The process voltage PV is a voltage at a voltage level that varies depending on process variation. The flag signal FLAG<1:5> is a signal including five (5) bits, but may be generated to include a different quantity of bits according to an embodiment.

The counting detection signal generation circuit CD GEN 240 generates a counting detection signal CD<1:5> based on the counting signal (CNT<1:8> in FIG. 10) that is based on a count of pulses of the cycle signal VCO and a first target counting signal TTF<1:8>, a second target counting signal TFF<1:8>, a third target counting signal TSS<1:8>, and a fourth target counting signal TFT<1:8>. The counting detection signal generation circuit 240 generates, based on pulses of the cycle signal VCO while the counting enable signal CEN is enabled, the counting detection signal CD<1:5> by comparing the counting signal (CNT<1:8> in FIG. 10) with the first target counting signal TTF<1:8>, the second target counting signal TFF<1:8>, the third target counting signal TSS<1:8>, and the fourth target counting signal TFT<1:8>. The counting detection signal CD<1:5> is a signal including five (5) bits, but may be generated to include a different quantity of bits according to an embodiment. Each of the counting signal (CNT<1:8> in FIG. 10), the first target counting signal TTF<1:8>, the second target counting signal TFF<1:8>, the third target counting signal TSS<1:8>, and the fourth target counting signal TFT<1:8> is a signal including eight (8) bits, but may be generated to include a different quantity of bits according to an embodiment.

The process information signal generation circuit 250 generates the process information signal PINF<1:9> that indicates process variation based on the counting detection signal CD<1:5> and the flag signal FLAG<1:5>. The process information signal generation circuit 250 generates the process information signal PINF<1:9> based on a combination of the logic levels of the bits of the counting detection signal CD<1:5> and the flag signal FLAG<1:5>. The process information signal PINF<1:9> is a signal including nine (9) bits, but may be generated to include a different quantity of bits according to an embodiment.

After the start of a process variation detection operation while the process detection enable signal PD_EN is enabled, the semiconductor device 20 generates the flag signal FLAG<1:5> by comparing the voltage levels of the reference voltages (VREF1, VREF2, VREF3, and VREF4 in FIG. 4) and the process voltage (PV in FIG. 4) having a voltage level that varies depending on process variation. After the start of a process variation detection operation, the semiconductor device 20 generates the process information signal PINF<1:9> that indicates process variation based on the flag signal FLAG<1:5> and the counting detection signal CD<1:5> that is generated based on timing of pulses of the cycle signal VCO.

FIG. 3 is a diagram illustrating a cycle signal generation circuit 220 that is included, for example, in the semiconductor device 20 according to an embodiment of the present disclosure. As illustrated in FIG. 3, the cycle signal generation circuit 220 includes an enable signal generation circuit 221 and a voltage supply circuit 222. The enable signal generation circuit 221 is implemented with inverters 221<1> and 221<2>. The enable signal generation circuit 221 generates an inverted enable signal ENB by inverting the voltage enable signal VEN. The enable signal generation circuit 221 generates an enable signal END by inverting the inverted enable signal ENB. The enable signal generation circuit 221 generates the inverted enable signal ENB at a logic low level and the enable signal END at a logic high level when the voltage enable signal VEN is enabled at a logic high level. The enable signal generation circuit 221 generates the inverted enable signal ENB at a logic high level and the enable signal END at a logic low level when the voltage enable signal VEN is disabled at a logic low level.

The voltage supply circuit 222 includes a first supply voltage generation circuit 222_1, a second supply voltage generation circuit 222_2, a connection circuit 222_3, a charge discharge circuit 222_4, and an oscillator ROD 223.

The first supply voltage generation circuit 222_1 includes a PMOS transistor 222<1> that is disposed between a power source voltage VDD and a node nd221 and that is turned on when the enable signal END is generated at a logic low level, a PMOS transistor 222<2> that is disposed between the power source voltage VDD and the node nd221 and that is turned on when the voltage level of the node nd221 is at the voltage level of a ground voltage VSS, a PMOS transistor 222<3> that is disposed between the power source voltage VDD and a node nd222 and that is turned on when the voltage level of the node nd221 is at the voltage level of the ground voltage VSS, a PMOS transistor 222<4> that is disposed between the power source voltage VDD and the node nd222 and that is turned on when the enable signal END is generated at a logic low level, and a PMOS transistor 222<5> that is disposed between the power source voltage VDD and a node nd223 and that is turned on when the voltage level of the node nd221 is at the voltage level of the ground voltage VSS.

The PMOS transistor 222<1> and PMOS transistor 222<4> of the first supply voltage generation circuit 222_1 are turned on when the enable signal END is generated at a logic low level. The first supply voltage generation circuit 222_1 drives the node nd221 and the node nd222 to the voltage level of the power source voltage VDD when the PMOS transistor 222<1> and the PMOS transistor 222<4> are turned on when the enable signal END is generated at a logic low level. The first supply voltage generation circuit 222_1 drives the node nd223 to the voltage level of the power source voltage VDD when the node nd221 is driven at the voltage level of the ground voltage VSS as the charge of the node nd221 is discharged. The first supply voltage generation circuit 222_1 generates the first supply voltage VSUP1 by driving the node nd223 to the voltage level of the power source voltage VDD when the node nd221 is driven at the voltage level of the ground voltage VSS.

The first supply voltage generation circuit 222_1 generates the first supply voltage VSUP1 at a low voltage level when the driving forces of the PMOS transistor 222<1>, the PMOS transistor 222<2>, the PMOS transistor 222<3>, the PMOS transistor 222<4>, and the PMOS transistor 222<5> are reduced when process variation is lower. The first supply voltage generation circuit 222_1 generates the first supply voltage VSUP1 at a high voltage level when the driving forces of the PMOS transistor 222<1>, the PMOS transistor 222<2>, the PMOS transistor 222<3>, the PMOS transistor 222<4>, and the PMOS transistor 222<5> are increased when process variation is higher.

The second supply voltage generation circuit 222_2 includes an NMOS transistor 222<6> that is disposed between a node nd225 and the ground voltage VSS and that is turned on when the inverted enable signal ENB is generated at a logic high level, an NMOS transistor 222<7> that is disposed between the node nd225 and the ground voltage VSS and that is turned on when the voltage level of the node nd225 is at the voltage level of the power source voltage VDD, and an NMOS transistor 222<8> that is disposed between a node nd226 and the ground voltage VSS and that is turned on when the voltage level of the node nd225 is at the voltage level of the power source voltage VDD.

The NMOS transistor 222<6> of the second supply voltage generation circuit 222_2 is turned on when the inverted enable signal ENB is generated at a logic high level. The second supply voltage generation circuit 222_2 drives the node nd225 to the voltage level of the ground voltage VSS when the NMOS transistor 222<6> is turned on when the inverted enable signal ENB is generated at a logic high level. The NMOS transistor 222<7> and NMOS transistor 222<8> of the second supply voltage generation circuit 222_2 are turned on when the node nd225 is driven at the voltage level of the power source voltage VDD. The second supply voltage generation circuit 222_2 drives the node nd226 to the voltage level of the ground voltage VSS when the NMOS transistor 222<8> is turned on when the node nd225 is driven at the voltage level of the power source voltage VDD. The second supply voltage generation circuit 222_2 generates the second supply voltage VSUP2 by driving the node nd226 at the voltage level of the ground voltage VSS when the node nd225 is driven at the voltage level of the power source voltage VDD.

The second supply voltage generation circuit 222_2 generates the second supply voltage VSUP2 at a high voltage level when the driving forces of the NMOS transistor 222<6>, the NMOS transistor 222<7>, and the NMOS transistor 222<8> are reduced when process variation is lower. The second supply voltage generation circuit 222_2 generates the second supply voltage VSUP2 at a low voltage level when the driving forces of the NMOS transistor 222<6>, the NMOS transistor 222<7>, and the NMOS transistor 222<8> are increased when process variation is higher.

The connection circuit 222_3 includes a switch 222<9> that is disposed between the node nd222 and the node nd225 and that is turned on when the enable signal END is generated at a logic high level and the inverted enable signal ENB is generated at a logic low level.

The connection circuit 222_3 connects the current path of the node nd222 and the node nd225 when the switch 222<9> is turned on when the enable signal END is generated at a logic high level and the inverted enable signal ENB is generated at a logic low level. The connection circuit 222_3 blocks the current path of the node nd222 and the node nd225 when the switch 222<9> is turned off when the enable signal END is generated at a logic low level and the inverted enable signal ENB is generated at a logic high level. The current path includes, for example, a path or route of a current that flows from the power source voltage VDD to the ground voltage VSS through the node nd222 and the node nd225.

The charge discharge circuit 222_4 includes a resistor 222<10> that is disposed between the node nd221 and a node nd224 and an NMOS transistor 222<11> that is disposed between the node nd224 and the ground voltage VSS and that is turned on when the enable signal END is generated at a logic high level.

The charge discharge circuit 222_4 discharges the charge of the node nd221 to the ground voltage VSS when the enable signal END is generated at a logic high level.

The oscillator 223 is disposed between the node nd223 and the node nd226 and is supplied with the first supply voltage VSUP1 and the second supply voltage VSUP2. The oscillator 223 generates the cycle signal VCO including pulses that are periodically generated while the cycle enable signal OEN is enabled at a logic high level. The oscillator 223 may be implemented as a ring oscillator in which an odd number of inverters are connected in series when the cycle enable signal OEN is enabled at a logic high level. The oscillator 223 generates the cycle signal VCO having a cycle or frequency at which a pulse is generated. The oscillator 223 increases the cycle or frequency of pulse generation when the first supply voltage VSUP1 is generated at a low level and the second supply voltage VSUP2 is generated at a high level when process variation is lower. The oscillator 223 reduces the cycle or frequency of pulse generation when the first supply voltage VSUP1 is generated at a high level and the second supply voltage VSUP2 is generated at a low level when process variation is higher.

FIG. 4 is a diagram illustrating a comparison circuit 230 that is included, for example, in the semiconductor device 20 according to an embodiment of the present disclosure. As illustrated in FIG. 4, the comparison circuit 230 includes a process voltage generation circuit 231, a reference voltage generation circuit VREF GEN 232, and a flag signal generation circuit FLAG GEN 233.

The process voltage generation circuit 231 includes a PMOS transistor 231<1> that is disposed between the power source voltage VDD and a node nd231 and an NMOS transistor 231<2> that is disposed between the node nd231 and the ground voltage VSS. The PMOS transistor 231<1> is turned on when the process voltage PV is driven at the voltage level of the ground voltage VSS. The NMOS transistor 231<2> is turned on when the process voltage PV is driven at the voltage level of the power source voltage VDD.

The process voltage generation circuit 231 may drive the process voltage PV to the voltage level of the power source voltage VDD as the PMOS transistor 231<1> is turned on when the process voltage PV is driven at the voltage level of the ground voltage VSS. The process voltage generation circuit 231 may drive the process voltage PV to the voltage level of the ground voltage VSS as the NMOS transistor 231<2> is turned on when the process voltage PV is driven at the voltage level of the power source voltage VDD.

The process voltage generation circuit 231 generates the process voltage PV that is driven at a low level when process variation is lower. The process voltage generation circuit 231 generates the process voltage PV that is driven at a high level when process variation is higher.

The reference voltage generation circuit 232 generates a first reference voltage VREF1, a second reference voltage VREF2, a third reference voltage VREF3, and a fourth reference voltage VREF4 by dividing the power source voltage VDD through a plurality of resistors. The first reference voltage VREF1, the second reference voltage VREF2, the third reference voltage VREF3, and the fourth reference voltage VREF4 are each generated at a constant voltage level unaffected by process variation. The first reference voltage VREF1 is generated at a higher voltage level than the second reference voltage VREF2. The second reference voltage VREF2 is generated at a higher voltage level than the third reference voltage VREF3. The third reference voltage VREF3 is generated at a higher voltage level than the fourth reference voltage VREF4.

The flag signal generation circuit 233 generates the flag signal FLAG<1:5> based on the voltage levels of the process voltage PV, compared with the first reference voltage VREF1, the second reference voltage VREF2, the third reference voltage VREF3, and the fourth reference voltage VREF4 while the comparison enable signal SEN is enabled at a logic high level. The flag signal generation circuit 233 generates the flag signal FLAG<1:5> by comparing the voltage level of the process voltage PV with each of the first reference voltage VREF1, the second reference voltage VREF2, the third reference voltage VREF3 and the fourth reference voltage VREF4 while the comparison enable signal SEN is enabled at a logic high level. The flag signal generation circuit 233 generates the flag signal FLAG<1:5> with all bits disabled at a logic low level when the comparison enable signal SEN is disabled at a logic low level.

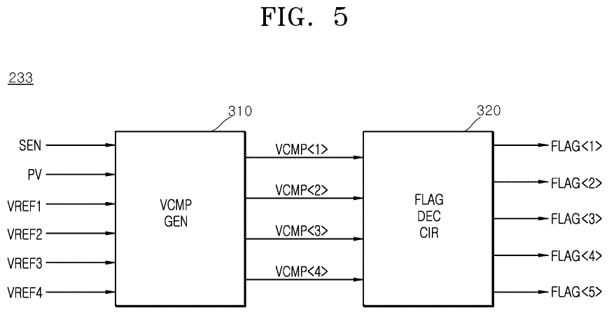

FIG. 5 is a block diagram illustrating a flag signal generation circuit 233 that is included, for example, in the comparison circuit 230 according to an embodiment of the present disclosure. As illustrated in FIG. 5, the flag signal generation circuit 233 includes a comparison voltage signal generation circuit VCMP GEN 310 and a flag signal decoding circuit FLAG DEC CIR 320.

The comparison voltage signal generation circuit 310 generates a comparison voltage signal VCMP<1:4> based on the voltage levels of the process voltage PV compared to the first reference voltage VREF1, the second reference voltage VREF2, the third reference voltage VREF3, and the fourth reference voltage VREF4 while the comparison enable signal SEN is enabled at a logic high level. The comparison voltage signal generation circuit 310 generates the comparison voltage signal VCMP<1:4> by comparing the voltage levels of the process voltage PV with the first reference voltage VREF1, the second reference voltage VREF2, the third reference voltage VREF3, and the fourth reference voltage VREF4 while the comparison enable signal SEN is enabled at a logic high level. The comparison voltage signal generation circuit 310 generates the comparison voltage signal VCMP<1:4> with all bits generated at a logic high level when the comparison enable signal SEN is disabled at a logic low level. The comparison voltage signal VCMP<1:4> is a signal including four (4) bits, but may be generated to include a different quantity of bits according to an embodiment.

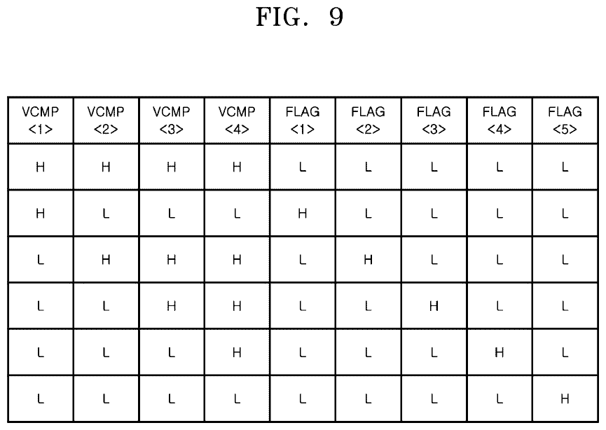

The flag signal decoding circuit 320 generates the flag signal FLAG<1:5> based on a combination of the logic levels of the bits of the comparison voltage signal VCMP<1:4>. The flag signal decoding circuit 320 generates the flag signal FLAG<1:5> that is selectively enabled by decoding the comparison voltage signal VCMP<1:4>. An operation including generating, by the flag signal decoding circuit 320, the flag signal FLAG<1:5> that is selectively enabled based on a combination of the logic levels of the bits of the comparison voltage signal VCMP<1:4> is described in detail with reference to FIG. 9.

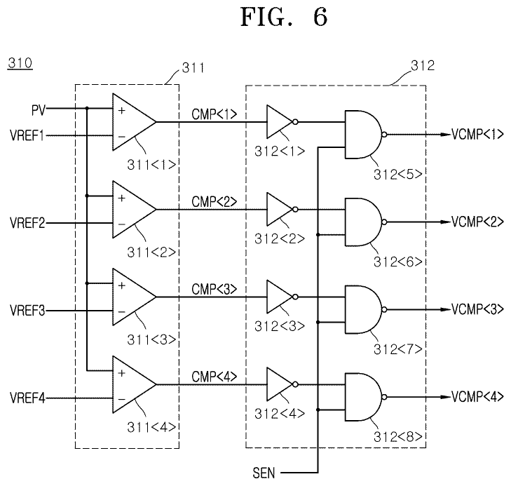

FIG. 6 is a diagram illustrating a comparison voltage signal generation circuit 310 that is included, for example, in the flag signal generation circuit 233 according to an embodiment of the present disclosure. As illustrated in FIG. 6, the comparison voltage signal generation circuit 310 includes a comparison signal generation circuit 311 and a comparison voltage signal output circuit 312.

The comparison signal generation circuit 311 includes a first comparator 311<1>, a second comparator 311<2>, a third comparator 311<3>, and a fourth comparator 311<4>.

The first comparator 311<1> generates a first bit CMP<1> of a comparison signal by comparing the process voltage PV and the first reference voltage VREF1. The first comparator 311<1> generates the first bit CMP<1> of the comparison signal at a logic high level when the voltage level of the process voltage PV is higher than the voltage level of the first reference voltage VREF1. The first comparator 311<1> generates the first bit CMP<1> of the comparison signal at a logic low level when the voltage level of the process voltage PV is equal to or lower than the voltage level of the first reference voltage VREF1.

The second comparator 311<2> generates a second bit CMP<2> of the comparison signal by comparing the process voltage PV and the second reference voltage VREF2. The second comparator 311<2> generates the second bit CMP<2> of the comparison signal at a logic high level when the voltage level of the process voltage PV is higher than the voltage level of the second reference voltage VREF2. The second comparator 311<2> generates the second bit CMP<2> of the comparison signal at a logic low level when the voltage level of the process voltage PV is equal to or lower than the voltage level of the second reference voltage VREF2.

The third comparator 311<3> generates a third bit CMP<3> of the comparison signal by comparing the process voltage PV and the third reference voltage VREF3. The third comparator 311<3> generates the third bit CMP<3> of the comparison signal at a logic high level when the voltage level of the process voltage PV is higher than the voltage level of the third reference voltage VREF3. The third comparator 311<3> generates the third bit CMP<3> of the comparison signal at a logic low level when the voltage level of the process voltage PV is equal to or lower than the voltage level of the third reference voltage VREF3.

The fourth comparator 311<4> generates a fourth bit CMP<4> of the comparison signal by comparing the process voltage PV and the fourth reference voltage VREF4. The fourth comparator 311<4> generates the fourth bit CMP<4> of the comparison signal at a logic high level when the voltage level of the process voltage PV is higher than the voltage level of the fourth reference voltage VREF4. The fourth comparator 311<4> generates the fourth bit CMP<4> of the comparison signal at a logic low level when the voltage level of the process voltage PV is equal to or lower than the voltage level of the fourth reference voltage VREF4.

The comparison voltage signal output circuit 312 is implemented with inverters 312<1>, 312<2>, 312<3>, and 312<4> and NAND gates 312<5>, 312<6>, 312<7>, and 312<8>.

The inverter 312<1> and the NAND gate 312<5> generate a first bit VCMP<1> of the comparison voltage signal by buffering the first bit CMP<1> of the comparison signal while the comparison enable signal SEN is enabled at a logic high level. The NAND gate 312<5> generates the first bit VCMP<1> of the comparison voltage signal at a logic high level while the comparison enable signal SEN is disabled at a logic low level.

The inverter 312<2> and the NAND gate 312<6> generate a second bit VCMP<2> of the comparison voltage signal by buffering the second bit CMP<2> of the comparison signal while the comparison enable signal SEN is enabled at a logic high level. The NAND gate 312<6> generates the second bit VCMP<2> of the comparison voltage signal at a logic high level while the comparison enable signal SEN is disabled at a logic low level.

The inverter 312<3> and the NAND gate 312<7> generate a third bit VCMP<3> of the comparison voltage signal by buffering the third bit CMP<3> of the comparison signal while the comparison enable signal SEN is enabled at a logic high level. The NAND gate 312<7> generates the third bit VCMP<3> of the comparison voltage signal at a logic high level while the comparison enable signal SEN is disabled at a logic low level.

The inverter 312<4> and the NAND gate 312<8> generate a fourth bit VCMP<4> of the comparison voltage signal by buffering the fourth bit CMP<4> of the comparison signal while the comparison enable signal SEN is enabled at a logic high level. The NAND gate 312<8> generates the fourth bit VCMP<4> of the comparison voltage signal at a logic high level while the comparison enable signal SEN is disabled at a logic low level.

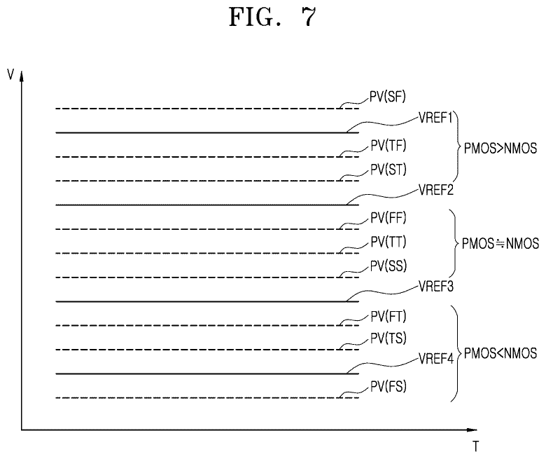

FIG. 7 is a voltage diagram illustrating process voltages that are generated depending on process variation and reference voltage according to an embodiment of the present disclosure. The voltage level of the process voltage PV generated depending on process variation and the reference voltages VREF1, VREF2, VREF3, and VREF4 are described with reference to FIG. 7.

The voltage level of the process voltage PV is higher than the voltage level of the first reference voltage VREF1 when process variation is at a first variance SF.

The voltage level of the process voltage PV is lower than the voltage level of the first reference voltage VREF1 and higher than the voltage level of the second reference voltage VREF2 when process variation is at a second variance TF or a third variance ST. The second variance TF is a process variance smaller than the first variance SF and greater than the third variance ST. In an example of the second variance TF, the process voltage PV is generated at a voltage level that is lower than the voltage level of the process voltage PV when process variation is at the first variance SF and is generated at a voltage higher than the voltage level of the process voltage PV when process variation is at the third variance ST. In an example of the third variance ST, the process voltage PV is generated at a voltage level that is lower than the voltage level of the process voltage PV when process variation is at the second variance TF and is generated at a voltage higher than the voltage level of the process voltage PV when process variation is at the fourth variance FF.

When process variation is at the first variance SF, the second variance TF, or the third variance ST, the driving force of the PMOS transistor 231<1> of the process voltage generation circuit 231 is greater than the driving force of the NMOS transistor 231<2> of the process voltage generation circuit 231.

The voltage level of the process voltage PV is lower than the voltage level of the second reference voltage VREF2 and higher than the voltage level of the third reference voltage VREF3 when process variation is at a fourth variance FF, a fifth variance TT, or a sixth variance SS. The fourth variance FF is a process variance smaller than the third variance ST and greater than the fifth variance TT. The fifth variance TT is a process variance smaller than the fourth variance FF and greater than the sixth variance SS. In an example of the fourth variance FF, the process voltage PV is generated at a voltage level that is lower than the voltage level of the process voltage PV when process variation is at the third variance ST and is generated at a voltage higher than the voltage level of the process voltage PV when process variation is at the fifth variance TT. In an example of the fifth variance TT, the process voltage PV is generated at a voltage level that is lower than the voltage level of the process voltage PV when process variation is at the fourth variance FF and is generated at a voltage higher than the voltage level of the process voltage PV when process variation is at the sixth variance SS. In an example of the sixth variance SS, the process voltage PV is generated at a voltage level that is lower than the voltage level of the process voltage PV when process variation is at the fifth variance TT and is generated at a voltage higher than the voltage level of the process voltage PV when process variation is at the seventh variance FT.

When process variation is at the fourth variance FF, the fifth variance TT, or the sixth variance SS the driving forces of the PMOS transistor 231<1> and NMOS transistor 231<2> of the process voltage generation circuit 231 are the same or similar.

The voltage level of the process voltage PV is lower than the voltage level of the third reference voltage VREF3 and higher than the voltage level of the fourth reference voltage VREF4 when process variation is at a seventh variance FT or an eighth variance TS. The seventh variance FT is process variance smaller than the sixth variance SS and greater than the eighth variance TS. The eight variance TS is process variance smaller than the seventh variance SS and greater than the ninth variance FS. In an example of the seventh variance FT, the process voltage PV is generated at a voltage level that is lower than the voltage level of the process voltage PV when process variation is at the sixth variance SS and is generated at a voltage higher than the voltage level of the process voltage PV when process variation is at the eighth variance TS. In an example of the eighth variance TS, the process voltage PV is generated at a voltage level that is lower than the voltage level of the process voltage PV when process variation is at the seventh variance FT and is generated at a voltage higher than the voltage level of the process voltage PV when process variation is at the ninth variance FS.

The voltage level of the process voltage PV is lower than the voltage level of the fourth reference voltage VREF4 when process variation is at a ninth variance FS. In an example of the ninth variance FS, the process voltage PV is generated at a voltage level that is lower than the voltage level of the process voltage PV when process variation is at the eighth variance TS.

When process variation is at the seventh variance FT, the eighth variance TS, or the ninth variance FS the driving force of the PMOS transistor 231<1> of the process voltage generation circuit 231 is smaller than the driving force of the NMOS transistor 231<2> of the process voltage generation circuit 231.

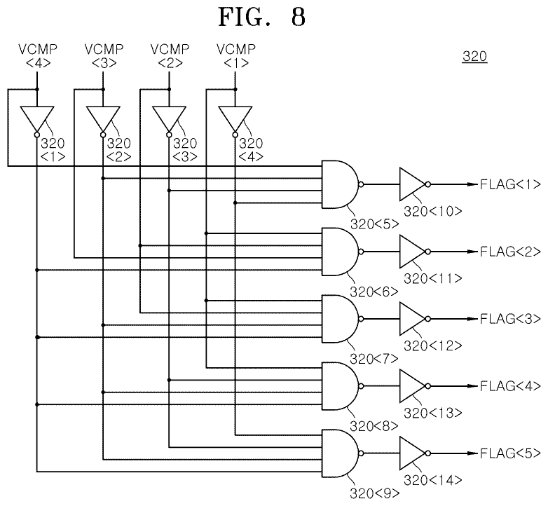

FIG. 8 is a circuit diagram illustrating a flag signal decoding circuit 320 that is included, for example, in the flag signal generation circuit 233 according to an embodiment of the present disclosure. As illustrated in FIG. 8, the flag signal decoding circuit 320 may be implemented with inverters 320<1>, 320<2>, 320<3>, 320<4>, 320<10>, 320<11>, 320<12>, 320<13>, and 320<14> and NAND gates 320<5>, 320<6>, 320<7>, 320<8>, and 320<9>.

The inverter 320<1> inverts the fourth bit VCMP<4> of the comparison voltage signal and outputs the result.

The inverter 320<2> inverts the third bit VCMP<3> of the comparison voltage signal and outputs the result.

The inverter 320<3> inverts the second bit VCMP<2> of the comparison voltage signal and outputs the result.

The inverter 320<4> inverts the first bit VCMP<1> of the comparison voltage signal and outputs the result.

The NAND gate 320<5> and the inverter 320<10> generate a first bit FLAG<1> of the flag signal at a logic high level when the fourth bit VCMP<4> of the comparison voltage signal is at a logic high level, the output signal of the inverter 320<2> is at a logic high level, the output signal of the inverter 320<3> is at a logic high level, and the output signal of the inverter 320<4> is at a logic high level. All other combinations of inputs to the NAND gate 320<5> result in the inverter 320<10> generating a first bit FLAG<1> of the flag signal at a logic low level.

The NAND gate 320<6> and the inverter 320<11> generate a second bit FLAG<2> of the flag signal at a logic high level when the output signal of the inverter 320<1> is at a logic high level, the third bit VCMP<3> of the comparison voltage signal is at a logic high level, the second bit VCMP<2> of the comparison voltage signal is at a logic high level, and the first bit VCMP<1> of the comparison voltage signal is at a logic high level. All other combinations of inputs to the NAND gate 320<6> result in the inverter 320<11> generating a second bit FLAG<2> of the flag signal at a logic low level.

The NAND gate 320<7> and the inverter 320<12> generate a third bit FLAG<3> of the flag signal at a logic high level when the output signal of the inverter 320<1> is at a logic high level, the output signal of the inverter 320<2> is at a logic high level, the second bit VCMP<2> of the comparison voltage signal is at a logic high level, and the first bit VCMP<1> of the comparison voltage signal is at a logic high level. All other combinations of inputs to the NAND gate 320<7> result in the inverter 320<12> generating a third bit FLAG<3> of the flag signal at a logic low level.

The NAND gate 320<8> and the inverter 320<13> may generate a fourth bit FLAG<4> of the flag signal at a logic high level when the output signal of the inverter 320<1> is at a logic high level, the output signal of the inverter 320<2> is at a logic high level, the output signal of the inverter 320<3> is at a logic high level, and the first bit VCMP<1> of the comparison voltage signal is at a logic high level. All other combinations of inputs to the NAND gate 320<8> result in the inverter 320<13> generating a fourth bit FLAG<4> of the flag signal at a logic low level.

The NAND gate 320<9> and the inverter 320<14> generate the fifth bit FLAG<5> of the flag signal at a logic high level when the output signal of the inverter 320<1> is at a logic high level, the output signal of the inverter 320<2> is at a logic high level, the output signal of the inverter 320<3> is at a logic high level, and the output signal of the inverter 320<4> is at a logic high level. All other combinations of inputs to the NAND gate 320<9> result in the inverter 320<14> generating a fifth bit FLAG<5> of the flag signal at a logic low level.

FIG. 9 is a table including data output during operation of the flag signal decoding circuit, for example, as illustrated in FIG. 8. An operation including generating, by the flag signal decoding circuit 320, the flag signal FLAG<1:5> that is selectively enabled based on a combination of the logic levels of the bits of the comparison voltage signal VCMP<1:4> is described with reference to FIG. 9.

The flag signal decoding circuit 320 generates the bits FLAG<1:5> of the flag signal, which are all disabled at a logic low level L when the first bit VCMP<1> of the comparison voltage signal is at a logic high level H, the second bit VCMP<2> of the comparison voltage signal is at a logic high level H, the third bit VCMP<3> of the comparison voltage signal is at a logic high level H, and the fourth bit VCMP<4> of the comparison voltage signal is at a logic high level H.

The flag signal decoding circuit 320 generates the first bit FLAG<1> of the flag signal enabled at a logic high level H and the second bit FLAG<2> through the fifth bit FLAG<5> of the flag signal at a logic low level L when the first bit VCMP<1> of the comparison voltage signal is at a logic high level H, the second bit VCMP<2> of the comparison voltage signal is at a logic low level L, the third bit VCMP<3> of the comparison voltage signal is at a logic low level L, and the fourth bit VCMP<4> of the comparison voltage signal is at a logic low level L.

The flag signal decoding circuit 320 generates the second bit FLAG<2> of the flag signal enabled at a logic high level H and the first bit FLAG<1> and the third bit FLAG<3> through the fifth bit FLAG<5> of the flag signal disabled at a logic low level L when the first bit VCMP<1> of the comparison voltage signal is at a logic low level L, the second bit VCMP<2> of the comparison voltage signal is at a logic high level H, the third bit VCMP<3> of the comparison voltage signal is at a logic high level H, and the fourth bit VCMP<4> of the comparison voltage signal is at a logic high level H.

The flag signal decoding circuit 320 generates the third bit FLAG<3> of the flag signal enabled at a logic high level H and the first bit FLAG<1>, the second bit FLAG<2>, the fourth bit FLAG<4>, and the fifth bit FLAG<5> of the flag signal disabled at a logic low level L when the first bit VCMP<1> of the comparison voltage signal is at a logic low level L, the second bit VCMP<2> of the comparison voltage signal is at a logic low level L, the third bit VCMP<3> of the comparison voltage signal is at a logic high level H, and the fourth bit VCMP<4> of the comparison voltage signal is at a logic high level H.

The flag signal decoding circuit 320 generates the fourth bit FLAG<4> of the flag signal enabled at a logic high level H and the first bit FLAG<1>, the second bit FLAG<2>, the third bit FLAG<3>, and the fifth bit FLAG<5> of the flag signal disabled at a logic low level L when the first bit VCMP<1> of the comparison voltage signal is at a logic low level L, the second bit VCMP<2> of the comparison voltage signal is at a logic low level L, the third bit VCMP<3> of the comparison voltage signal is at a logic low level L, and the fourth bit VCMP<4> of the comparison voltage signal is at a logic high level H.

The flag signal decoding circuit 320 generates the fifth bit FLAG<5> of the flag signal enabled at a logic high level H and the first bit FLAG<1> through the fourth bit FLAG<4> of the flag signal disabled at a logic low level L when the first bit VCMP<1> of the comparison voltage signal is at a logic low level L, the second bit VCMP<2> of the comparison voltage signal has a logic low level L, the third bit VCMP<3> of the comparison voltage signal is at a logic low level L, and the fourth bit VCMP<4> of the comparison voltage signal is at a logic low level L.

FIG. 10 is a block diagram illustrating a counting detection signal generation circuit 240 that is included, for example, in the semiconductor device 20 according to an embodiment of the present disclosure. As illustrated in FIG. 10, the counting detection signal generation circuit 240 includes a counting circuit CNT CIR 241 and a counting comparison circuit CNT CMP CIR 242.

The counting circuit 241 generates a counting signal CNT<1:8> including bits that are sequentially counted based on the counting enable signal CEN and the cycle signal VCO. The counting circuit 241 generates the counting signal CNT<1:8> including bits that are sequentially counted each time a pulse of the cycle signal VCO is input during an interval within which the counting enable signal CEN is enabled.

For example, the counting circuit 241 generates a first bit CNT<1> or least significant bit of the counting signal, which first bit transitions to a logic high level from a logic low level, when a pulse of the cycle signal VCO is input for a first time during an interval within which the counting enable signal CEN is enabled. The counting circuit 241 generates the first bit CNT<1> of the counting signal, which first bit transitions to a logic low level from the logic high level, and a second bit CNT<2> of the counting signal, which second bit transitions to a logic high level from a logic low level, when a pulse of the cycle signal VCO is input for a second time during the interval within which the counting enable signal CEN is enabled. The generates the eight bits CNT<1:8> of the counting signal in a similar manner as each subsequent pulse of the cycle signal VCO is input to the counting circuit 241.

The counting comparison circuit 242 generates a counting detection signal CD<1:5> based on the flag signal FLAG<2:4>, the counting signal CNT<1:8>, the first target counting signal TTF<1:8>, the second target counting signal TFF<1:8>, the third target counting signal TSS<1:8>, and the fourth target counting signal TFT<1:8>. The counting comparison circuit 242 generates a first bit CD<1> of the counting detection signal by comparing the counting signal CNT<1:8> and the first target counting signal TTF<1:8> when the second bit FLAG<2> of the flag signal is enabled. The counting comparison circuit 242 generates the second bit through the fourth bit CD<2:4> of the counting detection signal by comparing the counting signal CNT<1:8>, the second target counting signal TFF<1:8>, and the third target counting signal TSS<1:8> when the third bit FLAG<3> of the flag signal is enabled. The counting comparison circuit 242 generates a fifth bit CD<5> of the counting detection signal by comparing the counting signal CNT<1:8> and the fourth target counting signal TFT<1:8> when the fourth bit FLAG<4> of the flag signal is enabled.

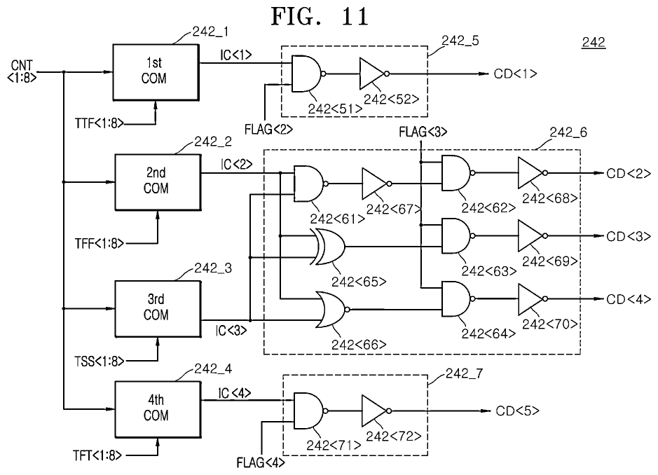

FIG. 11 is a diagram illustrating a counting comparison circuit 242 that is included, for example, in the counting detection signal generation circuit 240 according to an embodiment of the present disclosure. As illustrated in FIG. 11, the counting comparison circuit 242 includes a first counting comparator 1^{st} COM 242_1, a second counting comparator 2^{nd} COM 242_2, a third counting comparator 3^{rd} COM 242_3, a fourth counting comparator 4^{th} COM 242_4, a first logic circuit 242_5, a second logic circuit 242_6, and a third logic circuit 242_7.

The first counting comparator 242_1 generates a first bit IC<1> of an internal counting signal by comparing the counting signal CNT<1:8> and the first target counting signal TTF<1:8>. The first counting comparator 242_1 generates the first bit IC<1> of the internal counting signal enabled at a logic high level when the counting signal CNT<1:8> has a higher bit-wise value compared to the first target counting signal TTF<1:8>. The first target counting signal TTF<1:8> is a signal having a combination of logic levels that indicates when process variation is at the first variance SF as described with reference to FIG. 7.

The second counting comparator 242_2 generates a second bit IC<2> of the internal counting signal by comparing the counting signal CNT<1:8> and the second target counting signal TFF<1:8>. The second counting comparator 242_2 generates the second bit IC<2> of the internal counting signal enabled at a logic high level when the counting signal CNT<1:8> has a higher bit-wise value compared to the second target counting signal TFF<1:8>. The second target counting signal TFF<1:8> is a signal having a combination of logic levels that indicates when process variation is at one of the second variance TF and the third variance ST as described with reference to FIG. 7.

The third counting comparator 242_3 generates a third bit IC<3> of the internal counting signal by comparing the counting signal CNT<1:8> and the third target counting signal TSS<1:8>. The third counting comparator 242_3 generates the third bit IC<3> of the internal counting signal enabled at a logic high level when the counting signal CNT<1:8> has a higher bit-wise value compared to the third target counting signal TSS<1:8>. The third target counting signal TSS<1:8> is a signal having a combination of logic levels that indicates when process variation is at one of the fourth variance FF, the fifth variance TT, and the sixth variance SS as described with reference to FIG. 7.

The fourth counting comparator 242_4 generates a fourth bit IC<4> of the internal counting signal by comparing the counting signal CNT<1:8> and the fourth target counting signal TFT<1:8>. The fourth counting comparator 242_4 generates the fourth bit IC<4> of the internal counting signal enabled at a logic high level when the counting signal CNT<1:8> has a higher bit-wise value compared to the fourth target counting signal TFT<1:8>. The fourth target counting signal TFT<1:8> is a signal having a combination of logic levels that indicates when process variation is at one of the seventh variance FT, the eighth variance TS, and the ninth variance FS as described with reference to FIG. 7.

The first logic circuit 242_5 is implemented with a NAND gate 242<51> and an inverter 242<52>.

The first logic circuit 242_5 generates the first bit CD<1> of the counting detection signal by buffering the first bit IC<1> of the internal counting signal when the second bit FLAG<2> of the flag signal is enabled at a logic high level. The first logic circuit 242_5 generates the first bit CD<1> of the counting detection signal enabled at a logic high level when the second bit FLAG<2> of the flag signal is generated at have a logic high level and the first bit IC<1> of the internal counting signal is generated at a logic high level. The first logic circuit 242_5 generates the first bit CD<1> of the counting detection signal disabled at a logic low level when the second bit FLAG<2> of the flag signal is disabled at a logic low level.

The second logic circuit 242_6 is implemented with NAND gates 242<61>, 242<62>, 242<63>, 242<64>, an exclusive OR gate 242<65>, a NOR gate 242<66>, and inverters 242<67>, 242<68>, 242<69>, and 242<70>.

The second logic circuit 242_6 generates the second bit CD<2> of the counting detection signal by buffering the second bit IC<2> of the internal counting signal when the third bit FLAG<3> of the flag signal is enabled at a logic high level and the third bit IC<3> of the internal counting signal is enabled at a logic high level. The second logic circuit 242_6 generates the second bit CD<2> of the counting detection signal enabled at a logic high level when the third bit FLAG<3> of the flag signal is generated at a logic high level, the third bit IC<3> of the internal counting signal is generated at a logic high level, and the second bit IC<2> of the internal counting signal is generated at a logic high level. The second logic circuit 242_6 generates the second bit CD<2> of the counting detection signal disabled at a logic low level when the third bit FLAG<3> of the flag signal is disabled at a logic low level.

The second logic circuit 242_6 generates the third bit CD<3> of the counting detection signal when the third bit FLAG<3> of the flag signal is enabled at a logic high level and based on the logic levels of the second bit IC<2> of the internal counting signal and the third bit IC<3> of the internal counting signal. The second logic circuit 242_6 generates the third bit CD<3> of the counting detection signal enabled at a logic high level when the third bit FLAG<3> of the flag signal is generated at a logic high level, the third bit IC<3> of the internal counting signal is generated at a logic high level, and the second bit IC<2> of the internal counting signal is generated at a logic low level. The second logic circuit 242_6 generate the third bit CD<3> of the counting detection signal disabled at a logic low level when the third bit FLAG<3> of the flag signal is disabled at a logic low level.

The second logic circuit 242_6 generates the fourth bit CD<4> of the counting detection signal by inverting and buffering the second bit IC<2> of the internal counting signal when the third bit FLAG<3> of the flag signal is enabled at a logic high level and the third bit IC<3> of the internal counting signal is disabled at a logic low level. The second logic circuit 242_6 generates the fourth bit CD<4> of the counting detection signal enabled at a logic high level when the third bit FLAG<3> of the flag signal is generated at a logic high level, the third bit IC<3> of the internal counting signal is generated at a logic low level, and the second bit IC<2> of the internal counting signal is generated at a logic low level. The second logic circuit 242_6 generates the fourth bit CD<4> of the counting detection signal disabled at a logic low level when the third bit FLAG<3> of the flag signal is disabled at a logic low level.

The third logic circuit 242_7 is implemented with a NAND gate 242<71> and an inverter 242<72>.

The third logic circuit 242_7 generates the fifth bit CD<5> of the counting detection signal by buffering the fourth bit IC<4> of the internal counting signal when the fourth bit FLAG<4> of the flag signal is enabled at a logic high level. The third logic circuit 242_7 generates the fifth bit CD<5> of the counting detection signal enabled at a logic high level when the fourth bit FLAG<4> of the flag signal is generated at a logic high level and the fourth bit IC<4> of the internal counting signal is generated at a logic high level. The third logic circuit 242_7 generates the fifth bit CD<5> of the counting detection signal disabled at a logic low level when the fourth bit FLAG<4> of the flag signal is disabled at a logic low level.

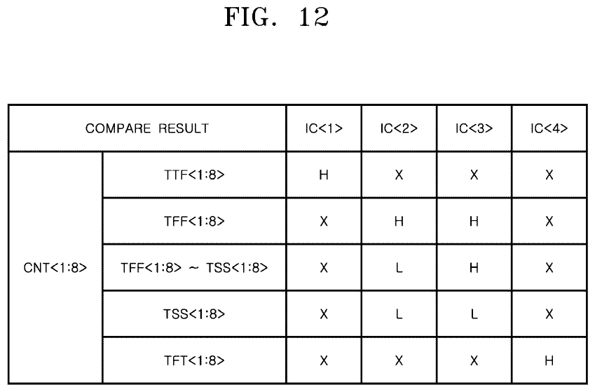

FIG. 12 is a table including data output during operation of the counting comparators 242_1, 242_2, 242_3, and 242_4, for example, as illustrated in FIG. 11. The operation of generating, by the counting comparators 242_1, 242_2, 242_3, and 242_4, the internal counting signal IC<1:4> by comparing the counting signal CNT<1:8> with the first target counting signal TTF<1:8>, the second target counting signal TFF<1:8>, the third target counting signal TSS<1:8>, and the fourth target counting signal TFT<1:8> is described with reference to FIG. 12.

During an example when process variation is at the first variance SF, the counting signal CNT<1:8> has a higher bit-wise value compared to the first target counting signal TTF<1:8>.

The first counting comparator 242_1 generates the first bit IC<1> of the internal counting signal enabled at a logic high level H by comparing the counting signal CNT<1:8> with the first target counting signal TTF<1:8>, resulting in the counting signal CNT<1:8> having a higher bit-wise value than the first target counting signal TTF<1:8> when process variation is at the first variance SF.

During an example when process variation is at one of the second variance TF and the third variance ST, the counting signal CNT<1:8> has a higher bit-wise value compared to the second target counting signal TFF<1:8>.

The second counting comparator 242_2 generates the second bit IC<2> of the internal counting signal enabled at a logic high level H by comparing the counting signal CNT<1:8> with the second target counting signal TFF<1:8>, resulting in the counting signal CNT<1:8> having a higher bit-wise value than the second target counting signal TFF<1:8> when process variation is at one of the second variance TF and the third variance ST. The third counting comparator 242_3 generates the third bit IC<3> of the internal counting signal enabled at a logic high level H by comparing the counting signal CNT<1:8> with the third target counting signal TSS<1:8>, resulting in the counting signal CNT<1:8> having a higher bit-wise value than the third target counting signal TSS<1:8> when process variation is at one of the second variance TF and the third variance ST.

During an example when process variation is at one of the fourth variance FF, the fifth variance TT, and the sixth variance SS, the counting signal CNT<1:8> has a lower bit-wise value compared to the second target counting signal TFF<1:8> and has a higher bit-wise value compared to the third target counting signal TSS<1:8>.

The second counting comparator 242_2 generates the second bit IC<2> of the internal counting signal disabled at a logic low level L by comparing the counting signal CNT<1:8> with the second target counting signal TFF<1:8>, resulting in the counting signal CNT<1:8> having a lower bit-wise value than the second target counting signal TFF<1:8> when process variation is at one of the fourth variance FF, the fifth variance TT, and the sixth variance SS. The third counting comparator 242_3 generates the third bit IC<3> of the internal counting signal enabled at a logic high level H by comparing the counting signal CNT<1:8> with the third target counting signal TSS<1:8>, resulting in the counting signal CNT<1:8> having a higher bit-wise value than the third target counting signal TSS<1:8> when process variation is at one of the fourth variance FF, the fifth variance TT, and the sixth variance SS.

During an example when process variation is at one of the seventh variance FT and the eighth variance TS, the counting signal CNT<1:8> has a lower bit-wise value compared to the third target counting signal TSS<1:8>.

The second counting comparator 242_2 generates the second bit IC<2> of the internal counting signal disabled at a logic low level L by comparing the counting signal CNT<1:8> with the second target counting signal TFF<1:8>, resulting in the counting signal CNT<1:8> having a lower bit-wise value than the second target counting signal TFF<1:8> when process variation is at one of the seventh variance FT and the eighth variance TS. The third counting comparator 242-3 generates the third bit IC<3> of the internal counting signal disabled at a logic low level L by comparing the counting signal CNT<1:8> with the third target counting signal TSS<1:8>, resulting in the counting signal CNT<1:8> having a lower bit-wise value than the third target counting signal TSS<1:8> when process variation is at one of the seventh variance FT and the eighth variance TS.

During an example when process variation is at the ninth variance FS, the counting signal CNT<1:8> has a higher bit-wise value compared to the fourth target counting signal TFT<1:8>.

The fourth counting comparator 242_4 generates the fourth bit IC<4> of the internal counting signal enabled at a logic high level H by comparing the counting signal CNT<1:8> with the fourth target counting signal TFT<1:8>, resulting in the counting signal CNT<1:8> having a higher bit-wise value than the first target counting signal TTF<1:8> when process variation is at the ninth variance FS.

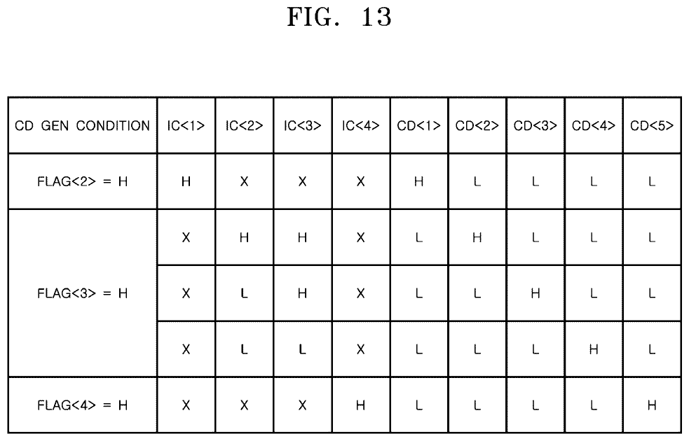

FIG. 13 is a table including data output during operation of the logic circuits 242_5, 242_6, and 242_7, for example, as illustrated in FIG. 11. The operation including generating, by the logic circuits 242_5, 242_6, and 242_7, the counting detection signal CD<1:5> based on the logic levels of the flag signal FLAG<2:4> and the internal counting signal IC<1:4> are described with reference to FIG. 13.

The first logic circuit 242_5 generates the first bit CD<1> of the counting detection signal at a logic high level H when the second bit FLAG<2> of the flag signal is enabled at a logic high level H and the first bit IC<1> of the internal counting signal is generated at a logic high level H.

The second logic circuit 242_6 generates the second bit CD<2> of the counting detection signal at a logic high level H when the third bit FLAG<3> of the flag signal is generated at a logic high level H, the third bit IC<3> of the internal counting signal is generated at a logic high level H, and the second bit IC<2> of the internal counting signal is generated at a logic high level H.

The second logic circuit 242_6 generates the third bit CD<3> of the counting detection signal at a logic high level H when the third bit FLAG<3> of the flag signal is generated at a logic high level H, the third bit IC<3> of the internal counting signal is generated at a logic high level H, and the second bit IC<2> of the internal counting signal is generated at a logic low level L.

The second logic circuit 242_6 generates the fourth bit CD<4> of the counting detection signal at a logic high level H when the third bit FLAG<3> of the flag signal is generated at a logic high level H, the third bit IC<3> of the internal counting signal is generated at a logic low level L, and the second bit IC<2> of the internal counting signal is generated at a logic low level L.

The third logic circuit 242_7 generates the fifth bit CD<5> of the counting detection signal at a logic high level H when the fourth bit FLAG<4> of the flag signal is generated at a logic high level H and the fourth bit IC<4> of the internal counting signal is generated at a logic high level H.

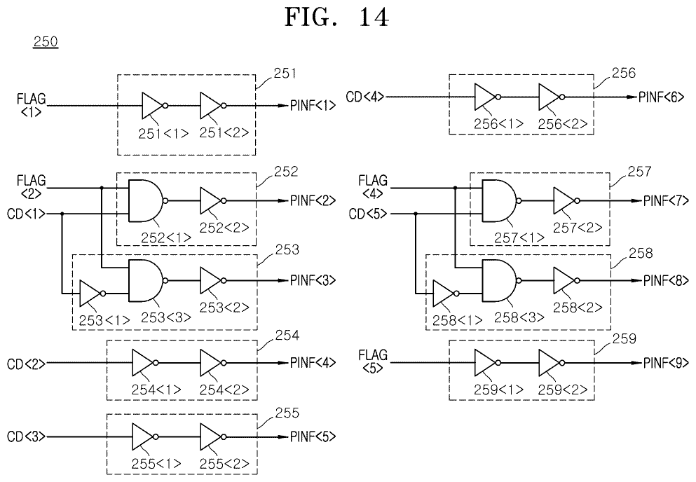

FIG. 14 is a circuit diagram illustrating a process information signal generation circuit 250 that is included, for example, in the semiconductor device 20 according to an embodiment of the present disclosure. As illustrated in FIG. 14, the process information signal generation circuit 250 includes a first process information signal generation circuit 251, a second process information signal generation circuit 252, a third process information signal generation circuit 253, a fourth process information signal generation circuit 254, a fifth process information signal generation circuit 255, a sixth process information signal generation circuit 256, a seventh process information signal generation circuit 257, an eighth process information signal generation circuit 258, and a ninth process information signal generation circuit 259.

The first process information signal generation circuit 251 is implemented with inverters 251<1> and 251<2>. The first process information signal generation circuit 251 generates the first bit PINF<1> of the process information signal by buffering the first bit FLAG<1> of the flag signal. The first process information signal generation circuit 251 generates the first bit PINF<1> of the process information signal at a logic high level when the first bit FLAG<1> of the flag signal is at a logic high level. The first process information signal generation circuit 251 generates the first bit PINF<1> of the process information signal at a logic low level when the first bit FLAG<1> of the flag signal is at a logic low level.

The second process information signal generation circuit 252 is implemented with a NAND gate 252<1> and an inverter 252<2>. The second process information signal generation circuit 252 generates the second bit PINF<2> of the process information signal by buffering the first bit CD<1> of the counting detection signal when the second bit FLAG<2> of the flag signal is at a logic high level. The second process information signal generation circuit 252 generates the second bit PINF<2> of the process information signal at a logic high level when the second bit FLAG<2> of the flag signal is at a logic high level and the first bit CD<1> of the counting detection signal is at a logic high level. The second process information signal generation circuit 252 generates the second bit PINF<2> of the process information signal at a logic low level when the second bit FLAG<2> of the flag signal is at a logic low level.

The third process information signal generation circuit 253 is implemented with inverters 253<1> and 253<2> and a NAND gate 253<3>. The third process information signal generation circuit 253 generates the third bit PINF<3> of the process information signal by inverting and buffering the first bit CD<1> of the counting detection signal when the second bit FLAG<2> of the flag signal is at a logic high level. The third process information signal generation circuit 253 generates the third bit PINF<3> of the process information signal at a logic high level when the second bit FLAG<2> of the flag signal is at a logic high level and the first bit CD<1> of the counting detection signal is at a logic low level. The third process information signal generation circuit 253 generates the third bit PINF<3> of the process information signal at a logic low level when the second bit FLAG<2> of the flag signal is at a logic low level.

The fourth process information signal generation circuit 254 is implemented with inverters 254<1> and 254<2>. The fourth process information signal generation circuit 254 generates the fourth bit PINF<4> of the process information signal by buffering the second bit CD<2> of the counting detection signal. The fourth process information signal generation circuit 254 generates the fourth bit PINF<4> of the process information signal at a logic high level when the second bit CD<2> of the counting detection signal is at a logic high level. The fourth process information signal generation circuit 254 generates the fourth bit PINF<4> of the process information signal at a logic low level when the second bit CD<2> of the counting detection signal is at a logic low level.

The fifth process information signal generation circuit 255 is implemented with inverters 255<1> and 255<2>. The fifth process information signal generation circuit 255 generates the fifth bit PINF<5> of the process information signal by buffering the third bit CD<3> of the counting detection signal. The fifth process information signal generation circuit 255 generates the fifth bit PINF<5> of the process information signal at a logic high level when the third bit CD<3> of the counting detection signal is at a logic high level. The fifth process information signal generation circuit 254 generates the fifth bit PINF<5> of the process information signal at a logic low level when the third bit CD<3> of the counting detection signal is at a logic low level.

The sixth process information signal generation circuit 256 is implemented with inverters 256<1> and 256<2>. The sixth process information signal generation circuit 256 generates the sixth bit PINF<6> of the process information signal by buffering the fourth bit CD<4> of the counting detection signal. The sixth process information signal generation circuit 256 generates the sixth bit PINF<6> of the process information signal at a logic high level when the fourth bit CD<4> of the counting detection signal is at a logic high level. The sixth process information signal generation circuit 256 generates the sixth bit PINF<6> of the process information signal at a logic low level when the fourth bit CD<4> of the counting detection signal is at a logic low level.

The seventh process information signal generation circuit 257 is implemented with a NAND gate 257<1> and an inverter 257<2>. The seventh process information signal generation circuit 257 generates the seventh bit PINF<7> of the process information signal by buffering the fifth bit CD<5> of the counting detection signal when the fourth bit FLAG<4> of the flag signal is at a logic high level. The seventh process information signal generation circuit 257 generates the seventh bit PINF<7> of the process information signal at a logic high level when the fourth bit FLAG<4> of the flag signal is a logic high level and the fifth bit CD<5> of the counting detection signal is at a logic high level. The seventh process information signal generation circuit 257 generates the seventh bit PINF<7> of the process information signal at a logic low level when the fourth bit FLAG<4> of the flag signal is at a logic low level.

The eighth process information signal generation circuit 258 is implemented with inverters 258<1> and 258<2> and a NAND gate 258<3>. The eighth process information signal generation circuit 258 generates the eighth bit PINF<8> of the process information signal by inverting and buffering the fifth bit CD<5> of the counting detection signal when the fourth bit FLAG<4> of the flag signal is at a logic high level. The eighth process information signal generation circuit 258 generates the eighth bit PINF<8> of the process information signal at a logic high level when the fourth bit FLAG<4> of the flag signal is at a logic high level and the fifth bit CD<5> of the counting detection signal is at a logic low level. The eighth process information signal generation circuit 258 generates the eighth bit PINF<8> of the process information signal at a logic low level when the fourth bit FLAG<4> of the flag signal is at a logic low level.

The ninth process information signal generation circuit 259 is implemented with inverters 259<1> and 259<2>. The ninth process information signal generation circuit 259 generates the ninth bit PINF<9> of the process information signal by buffering the fifth bit FLAG<5> of the flag signal. The ninth process information signal generation circuit 259 generates the ninth bit PINF<9> of the process information signal at a logic high level when the fifth bit FLAG<5> of the flag signal is at a logic high level. The ninth process information signal generation circuit 259 generates the ninth bit PINF<9> of the process information signal at a logic low level when the fifth bit FLAG<5> of the flag signal is at a logic low level.

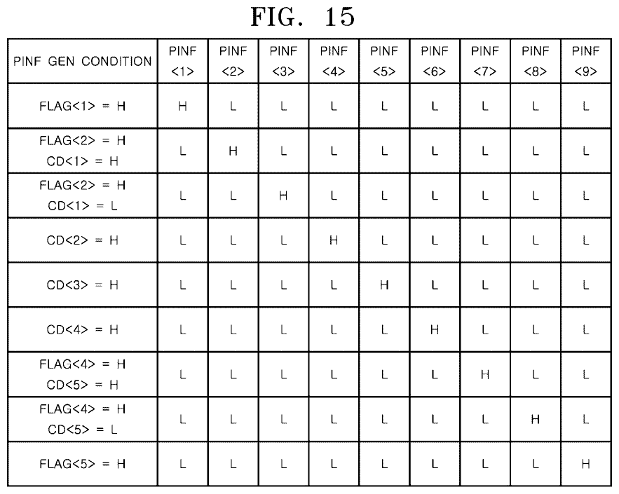

FIG. 15 is a table including data output during an operation of the process information signal generation circuit 250, such as illustrated in FIG. 14. The operation including generating, by the process information signal generation circuit 250, the process information signal PINF<1:9> based on the logic levels of the flag signal FLAG<1:5> and the counting detection signal CD<1:5> is described with reference to FIG. 15.

The first process information signal generation circuit 251 generates the first bit PINF<1> of the process information signal, which is at a logic high level H when the first bit FLAG<1> of the flag signal is at a logic high level H.

The second process information signal generation circuit 252 generates the second bit PINF<2> of the process information signal at a logic high level H when the second bit FLAG<2> of the flag signal is at a logic high level H and the first bit CD<1> of the counting detection signal is at a logic high level H.

The third process information signal generation circuit 253 generates the third bit PINF<3> of the process information signal at a logic high level H when the second bit FLAG<2> of the flag signal is at a logic high level H and the first bit CD<1> of the counting detection signal is at a logic low level L.

The fourth process information signal generation circuit 254 generates the fourth bit PINF<4> of the process information signal at a logic high level H when the second bit CD<2> of the counting detection signal is at a logic high level H.

The fifth process information signal generation circuit 255 generates the fifth bit PINF<5> of the process information signal at a logic high level H when the third bit CD<3> of the counting detection signal is at a logic high level H.

The sixth process information signal generation circuit 256 generates the sixth bit PINF<6> of the process information signal at a logic high level H when the fourth bit CD<4> of the counting detection signal is at a logic high level H.

The seventh process information signal generation circuit 257 generates the seventh bit PINF<7> of the process information signal at a logic high level H when the fourth bit FLAG<4> of the flag signal is at a logic high level H and the fifth bit CD<5> of the counting detection signal is at a logic high level H.

The eighth process information signal generation circuit 258 generates the eighth bit PINF<8> of the process information signal at a logic high level H when the fourth bit FLAG<4> of the flag signal is at a logic high level H and the fifth bit CD<5> of the counting detection signal is at a logic low level L.

The ninth process information signal generation circuit 259 generates the ninth bit PINF<9> of the process information signal at a logic high level H when the fifth bit FLAG<5> of the flag signal is at a logic high level H.

A process operation of the semiconductor system 1 according to an embodiment of the present disclosure is described with reference to FIG. 1 through FIG. 15. Examples when process variation is at the first variance SF, when process variation is at the third variance ST, and when process variation is at the fifth variance TT are described.

An example when the process variation is at the first variance SF is described.

The controller 10 transmits the clock signal CLK to the semiconductor device 20 through the first transmission line L11. The controller 10 transmits the process detection enable signal PD_EN to the semiconductor device 20 through the second transmission line L12.

The control circuit 210 generates the voltage enable signal VEN, the cycle enable signal OEN, and the comparison enable signal SEN that each are enabled at a logic high level at the time when the process detection enable signal PD_EN is enabled in synchronization with the clock signal CLK. The control circuit 210 generates the counting enable signal CEN that is enabled at a logic high level for the duration of an interval starting at the time when the process detection enable signal PD_EN is enabled in synchronization with the clock signal CLK.

The cycle signal generation circuit 220 supplies the oscillator 223 with the first supply voltage VSUP1 and the second supply voltage VSUP2 while the voltage enable signal VEN is enabled. The cycle signal generation circuit 220 generates the cycle signal VCO in the form of a pulse that is periodically generated from the first supply voltage VSUP1 and the second supply voltage VSUP2 while the cycle enable signal OEN is enabled.

While the comparison enable signal SEN is enabled, the comparison circuit 230 generates the flag signal FLAG<1:5> as a result of comparing the voltage levels of the first reference voltage VREF1, the second reference voltage VREF2, the third reference voltage VREF3, and the fourth reference voltage VREF4 with the process voltage PV that has a voltage level that varies depending on process variation. In this example, the process voltage PV is generated at a higher voltage level than the first reference voltage VREF1 because the process variation is at the first variance SF, and consequently, all of the bits of the flag signal FLAG<1:5> are disabled at a logic low level.

The counting detection signal generation circuit 240 generates the counting detection signal CD<1:5>, all the bits of which are disabled at a logic low level in this example, when the counting signal CNT<1:8> that counts pulses of the cycle signal VCO has a higher bit-wise value compared to the first target counting signal TTF<1:8>.

The process information signal generation circuit 250 generates the process information signal PINF<1:9>, all the bits of at a logic low level, by decoding the flag signal FLAG<1:5> all the bits of which are disabled at a logic low level, and the counting detection signal CD<1:5>, all the bits of which are disabled at a logic low level.

The controller 10 receives the process information signal PINF<1:9>, all the bits of which are at a logic low level, through the third transmission line L13 from the semiconductor device 20. The controller 10 detects that the process variation of the semiconductor device 20 is at the first variance SF when all the bits of the process information signal PINF<1:9> are generated at a logic low level.

An example when the process variation is at the third variance ST is described.

The controller 10 transmits the clock signal CLK to the semiconductor device 20 through the first transmission line L11. The controller 10 transmits the process detection enable signal PD_EN to the semiconductor device 20 through the second transmission line L12.

The control circuit 210 generates the voltage enable signal VEN, the cycle enable signal OEN, and the comparison enable signal SEN that are each enabled at a logic high level at the time when the process detection enable signal PD_EN is enabled in synchronization with the clock signal CLK. The control circuit 210 generates the counting enable signal CEN that is enabled at a logic high level for the duration of an interval starting at the time when the process detection enable signal PD_EN is enabled in synchronization with the clock signal CLK.

The cycle signal generation circuit 220 supplies the oscillator 223 with the first supply voltage VSUP1 and the second supply voltage VSUP2 while the voltage enable signal VEN is enabled. The cycle signal generation circuit 220 generates the cycle signal VCO in the form of a pulse that is periodically generated from the first supply voltage VSUP1 and the second supply voltage VSUP2 while the cycle enable signal OEN is enabled.

While the comparison enable signal SEN is enabled, the comparison circuit 230 generates the second bit FLAG<2> of the flag signal enabled at a logic high level as a result of comparing the voltage levels of the first reference voltage VREF1, the second reference voltage VREF2, the third reference voltage VREF3, and the fourth reference voltage VREF4 with the process voltage PV that has a voltage level that varies depending on process variation. In this example, the process voltage PV is generated at a voltage level between the first reference voltage VREF1 and the second reference voltage VREF2 because the process variation is at the third variance ST.

The counting detection signal generation circuit 240 generates the first bit CD<1> of the counting detection signal disabled at a logic low level in this example, when the counting signal CNT<1:8> that counts pulses of the cycle signal VCO has a lower bit-wise value compared to the first target counting signal TTF<1:8>.

The process information signal generation circuit 250 generates the third bit PINF<3> of the process information signal at a logic high level when the second bit FLAG<2> of the flag signal is at a logic high level and the first bit CD<1> of the counting detection signal is disabled at a logic low level.

The controller 10 receives the third bit PINF<3> of the process information signal at a logic high level through the third transmission line L13 from the semiconductor device 20. The controller 10 detects that the process variation of the semiconductor device 20 is at the third variance ST when the third bit PINF<3> of the process information signal is generated at a logic high level.

An example when the process variation is at the fifth variance TT is described.

The controller 10 transmits the clock signal CLK to the semiconductor device 20 through the first transmission line L11. The controller 10 transmits the process detection enable signal PD_EN to the semiconductor device 20 through the second transmission line L12.

The control circuit 210 generates the voltage enable signal VEN, the cycle enable signal OEN, and the comparison enable signal SEN that are each enabled at a logic high level at the time when the process detection enable signal PD_EN is enabled in synchronization with the clock signal CLK. The control circuit 210 generates the counting enable signal CEN that is enabled at a logic high level for the duration of an interval starting at the time when the process detection enable signal PD_EN is enabled in synchronization with the clock signal CLK.

The cycle signal generation circuit 220 supplies the oscillator 223 with the first supply voltage VSUP1 and the second supply voltage VSUP2 while the voltage enable signal VEN is enabled. The cycle signal generation circuit 220 generates the cycle signal VCO in the form of a pulse that is periodically generated from the first supply voltage VSUP1 and the second supply voltage VSUP2 while the cycle enable signal OEN is enabled.

While the comparison enable signal SEN is enabled, the comparison circuit 230 generates the third bit FLAG<3> of the flag signal enabled at a logic high level as a result of comparing the voltage levels of the first reference voltage VREF1, the second reference voltage VREF2, the third reference voltage VREF3, and the fourth reference voltage VREF4 with the process voltage PV that has a voltage level that varies depending on process variation. In this example, the process voltage PV is generated at a voltage level between the second reference voltage VREF2 and the third reference voltage VREF3 because the process variation is at the fifth variance TT.

The counting detection signal generation circuit 240 generates the third bit CD<3> of the counting detection signal enabled at a logic high level when the counting signal CNT<1:8> that counts pulses of the cycle signal VCO has a lower bit-wise value compared to the second target counting signal TFF<1:8> and has a higher bit-wise value compared to the third target counting signal TSS<1:8>.

The process information signal generation circuit 250 generate the fifth bit PINF<5> of the process information signal at a logic high level when the third bit CD<3> of the counting detection signal is enabled at a logic high level.

The controller 10 receives the fifth bit PINF<5> of the process information signal at a logic high level through the third transmission line L13 from the semiconductor device 20. The controller 10 detects that the process variation of the semiconductor device 20 is at the fifth variance TT when the fifth bit PINF<5> of the process information signal is generated at a logic high level.

The semiconductor system 1 according to an embodiment of the present disclosure may detect variance of process variation in various ways after the start of a process variation detection operation by generating the process information signal PINF<1:9> based on the voltage level of the process voltage PV that is generated depending on process variation and pulse timing of the cycle signal VCO. The semiconductor system 1 may accurately detect variance of process variation, after the start of a process variation detection operation, from the process information signal PINF<1:9> that indicates the process variation based on the flag signal FLAG<1:5> that is generated based on the process voltage PV that has a voltage level that varies depending on process variation and the counting detection signal CD<1:5> that is generated based on the cycle signal VCO having pulse timing that varies depending on process variation.

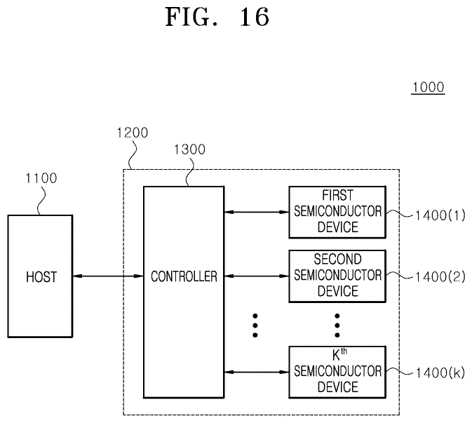

FIG. 16 is a block diagram illustrating an electronic system 1000 according to an embodiment of the present disclosure. As illustrated in FIG. 16, the electronic system 1000 includes a host 1100 and a semiconductor system 1200.

The host 1100 and the semiconductor system 1200 mutually transmit or communicate signals in both directions using an interface protocol. The interface protocol that is used between the host 1100 and the semiconductor system 1200 may include a multi-media card (MMC), an enhanced small disk interface (ESDI), integrated drive electronics (IDE), peripheral component interconnect-express (PCI-E), advanced technology attachment (ATA), serial ATA (SATA), parallel ATA (PATA), a serial attached SCSI (SAS), and a universal serial bus (USB).

The semiconductor system 1200 includes a controller 1300 and K semiconductor devices 1400(1:K). The controller 1300 controls a process variation detection operation of each of the semiconductor devices 1400(1:K), where K is a positive integer. The semiconductor devices 1400(1:K) each generate the process information signal PINF<1:9> based on the voltage level of the process voltage PV that is generated depending on process variation after the start of a process variation detection operation and time at which a pulse of the cycle signal VCO is generated. After the start of a process variation detection operation, the semiconductor devices 1400(1:K) each generate a process information signal PINF<1:9> that indicates process variation based on the flag signal FLAG<1:5> that is generated based on the process voltage PV having a voltage level that varies depending on process variation and the counting detection signal CD<1:5> that is generated based on the cycle signal VCO having pulse timing that varies depending on the process variation. The semiconductor devices 1400(1:K) each provide the process information signal PINF<1:9> to the controller 1300. The controller 1300 detects process variation in various ways after receiving the process information signal PINF<1:9> from the semiconductor devices 1400(1:K). The controller 1300 may accurately detect the process variation from the received process information signal PINF<1:9> from each of the semiconductor devices 1400(1:K).

The controller 1300 may be implemented similarly to the controller 10 illustrated in FIG. 1. The semiconductor devices 1400(1:K) may each be implemented similarly to the semiconductor device 20 illustrated in FIG. 1 and FIG. 2. According to an embodiment, the semiconductor devices 1400(1:K) may each be implemented with one of dynamic random access memory (DRAM), phase change random access memory (PRAM), resistive random access memory (RRAM), magnetic random access memory (MRAM), and ferroelectric random access memory (FRAM).

While the detailed embodiments of the present disclosure are disclosed in the present disclosure, those skilled in the art will understand that various modifications, additions, and substitutions related to these embodiments are possible without departing from the scope and technical spirit of the present disclosure. Therefore, the scope of the present disclosure should not be limited to the foregoing embodiments. All changes within the meaning and range of equivalency of the claims are included within their scope.

What is claimed is:

1. A semiconductor device comprising:
a comparison circuit configured to generate a flag signal by comparing a voltage level of a reference voltage with a voltage level of a process voltage after a start of a process variation detection operation; and
a process information signal generation circuit configured to generate a process information signal that indicates process variation based on a counting detection signal that is generated based on the flag signal and based on timing of pulses included in a cycle signal.

2. The semiconductor device of claim 1,
wherein the process voltage is a voltage having a voltage level that varies depending on the process variation, and
wherein the cycle signal is a signal having pulses generated at timing that varies depending on the process variation.

3. The semiconductor device of claim 1, wherein the comparison circuit comprises:
a process voltage generation circuit comprising a PMOS transistor and an NMOS transistor and configured to drive the process voltage based on a driving force of the PMOS transistor and a driving force of the NMOS transistor; and
a flag signal generation circuit configured to generate the flag signal by comparing the process voltage and the reference voltage during an interval while a comparison enable signal is enabled.

4. The semiconductor device of claim 3, wherein the process voltage generation circuit comprises:
the PMOS transistor disposed between a power source voltage and a first node and configured to drive the process voltage to a voltage level of the power source voltage when the process voltage is driven at a voltage level of a ground voltage; and
the NMOS transistor disposed between the first node and the ground voltage and configured to drive the process voltage to the voltage level of the ground voltage when the process voltage is driven at the voltage level of the power source voltage.

5. The semiconductor device of claim 3, wherein the flag signal generation circuit comprises:
a comparison voltage signal generation circuit configured to generate a comparison voltage signal by comparing the process voltage and the reference voltage during the interval while the comparison enable signal is enabled; and
a flag signal decoding circuit configured to generate the flag signal based on a combination of logic levels of bits of the comparison voltage signal.

6. The semiconductor device of claim 5, wherein the comparison voltage signal generation circuit comprises:
a comparison signal generation circuit configured to generate a comparison signal by comparing the process voltage and the reference voltage; and
a comparison voltage signal output circuit configured to generate the comparison voltage signal by buffering the comparison signal during the interval while the comparison enable signal is enabled and configured to generate the comparison voltage signal that is disabled during the interval while the comparison enable signal is disabled.

7. A semiconductor device comprising:
a cycle signal generation circuit configured to generate a cycle signal having pulses generated at timing that varies depending on process variation;
a counting detection signal generation circuit configured to generate a counting detection signal by comparing a target counting signal with a counting signal that counts pulses of the cycle signal; and
a process information signal generation circuit configured to generate a process information signal that indicates process variation based on the counting detection signal and a flag signal.

8. The semiconductor device of claim 7, wherein the cycle signal generation circuit is configured to:
increase a frequency of pulse generation of the cycle signal when the process variation is lower, and
reduce a frequency of pulse generation of the cycle signal when the process variation is higher.

9. The semiconductor device of claim 7, wherein the counting detection signal generation circuit comprises:
a counting circuit configured to generate the counting signal comprising bits that are sequentially counted based on pulses of the cycle signal received during an interval while a counting enable signal is enabled; and
a counting comparison circuit configured to generate the counting detection signal by comparing the counting signal and the target counting signal.

10. The semiconductor device of claim 7, further comprising a comparison circuit configured to generate the flag signal by comparing a reference voltage and a process voltage having a voltage level that varies depending on the process variation.

11. The semiconductor device of claim 10, wherein the comparison circuit comprises:
a process voltage generation circuit comprising a PMOS transistor and an NMOS transistor and configured to drive the process voltage based on a driving force of the PMOS transistor and a driving force of the NMOS transistor; and
a flag signal generation circuit configured to generate the flag signal by comparing the process voltage and the reference voltage during an interval while a comparison enable signal is enabled.

12. The semiconductor device of claim 11, wherein the process voltage generation circuit comprises:
the PMOS transistor disposed between a power source voltage and a first node and configured to drive the process voltage to a voltage level of the power source voltage when the process voltage is driven at a voltage level of a ground voltage; and
the NMOS transistor disposed between the first node and the ground voltage and configured to drive the process voltage to the voltage level of the ground voltage when the process voltage is driven at the voltage level of the power source voltage.

13. The semiconductor device of claim 11, wherein the flag signal generation circuit comprises:
a comparison voltage signal generation circuit configured to generate a comparison voltage signal by comparing the process voltage and the reference voltage during the interval while the comparison enable signal is enabled; and
a flag signal decoding circuit configured to generate the flag signal based on a combination of logic levels of bits of the comparison voltage signal.

14. The semiconductor device of claim 13, wherein the comparison voltage signal generation circuit comprises:
a comparison signal generation circuit configured to generate a comparison signal by comparing the process voltage and the reference voltage; and
a comparison voltage signal output circuit configured to generate the comparison voltage signal by buffering the comparison signal during the interval while the comparison enable signal is enabled and configured to generate the comparison voltage signal that is disabled during the interval while the comparison enable signal is disabled.

15. A semiconductor device comprising:
a comparison circuit configured to generate a plurality of flag signals in response to detecting a voltage level of a process voltage having a voltage level that varies depending on process variation;
a counting detection signal generation circuit configured to generate a plurality of counting detection signals by comparing a counting signal with a first target counting signal, a second target counting signal, a third target counting signal, and a fourth target counting signal, wherein the counting signal counts pulses of a cycle signal having pulse timing that varies depending on the process variation; and
a process information signal generation circuit configured to generate a plurality of process information signals that indicate the process variation based on the plurality of counting detection signals and the plurality of flag signals.

16. The semiconductor device of claim 15, wherein the comparison circuit generates the plurality of flag signals by comparing the process voltage with a first reference voltage, a second reference voltage, a third reference voltage, and a fourth reference voltage each at a constant voltage level unaffected by process variation.

17. The semiconductor device of claim 15, wherein the comparison circuit generates the plurality of flag signals based on a change in a driving force of a PMOS transistor and a driving force of an NMOS transistor, which PMOS transistor and NMOS transistor drive the process voltage.

18. The semiconductor device of claim 15, wherein the comparison circuit comprises:
a process voltage generation circuit comprising a PMOS transistor and an NMOS transistor and configured to drive the process voltage based on a driving force of the PMOS transistor and a driving force of the NMOS transistor; and
a flag signal generation circuit configured to generate the plurality of flag signals by comparing the process voltage and a plurality of reference voltages during an interval while a comparison enable signal is enabled.

19. The semiconductor device of claim 18, wherein the process voltage generation circuit comprises:
the PMOS transistor disposed between a power source voltage and a first node and configured to drive the process voltage to a voltage level of the power source voltage when the process voltage is driven at a voltage level of a ground voltage; and
the NMOS transistor disposed between the first node and the ground voltage and configured to drive the process voltage to the voltage level of the ground voltage when the process voltage is driven at the voltage level of the power source voltage.

20. The semiconductor device of claim 18, wherein the flag signal generation circuit comprises:
a comparison voltage signal generation circuit configured to generate a plurality of comparison voltage signals by comparing the process voltage and the plurality of reference voltages during the interval while the comparison enable signal is enabled; and
a flag signal decoding circuit configured to generate the plurality of flag signals based on a combination of logic levels of the plurality of comparison voltage signals.

21. The semiconductor device of claim 15, wherein the counting detection signal generation circuit comprises:
a counting circuit configured to generate the counting signal comprising bits that are sequentially counted based on pulses of the cycle signal received during an interval while a counting enable signal is enabled; and
a counting comparison circuit configured to generate the plurality of counting detection signals by comparing the counting signal with the first target counting signal, the second target counting signal, the third target counting signal, and the fourth target counting signal.

22. A method comprising:
generating a plurality of flag signals in response to detecting a process voltage that varies depending on process variation of a semiconductor device;
generating a counting signal that counts pulses of a cycle signal having pulse timing that varies depending on the process variation;
generating a plurality of counting detection signals by comparing the counting signal with each of a plurality of target counting signals; and
generating a process information signal that indicates the process variation based on the plurality of counting detection signals and the plurality of flag signals.
